(19) United States
(12) Patent Application Publication
(10) Pub. No.: US 2010/0055851 A1
(43) Pub. Date: Mar. 4, 2010

(54) PHOTORESIST COMPOSTION, METHOD FOR FORMING THIN FILM PATTERNS, AND METHOD FOR MANUFACTURING A THIN FILM TRANSISTOR USING THE SAME

(75) Inventors: Hi-Kuk Lee, Yongin-si (KR); Sang-Hyun Yun, Suwon-si (KR); Jung-In Park, Suwon-si (KR); Woo-Seok Jeon, Seongnam-si (KR); Pil-Soon Hong, Suwon-si (KR); Doek-Man Kang, Seongnam-si (KR); Sae-Tae Oh, Pyeongtaek-si (KR); Chang-Ik Lee, Cheonan-si (KR)

Correspondence Address: CANTOR COLBURN, LLP, 20 Church Street, 22nd Floor, Hartford, CT, 06103, US

(73) Assignees: Samsung Electronics Co., Ltd., Suwon-si (KR); AZ Electronic Materials (Japan) K.K., Tokyo (JP)

(21) Appl. No.: 12/389,031

(22) Filed: Feb. 19, 2009

(30) Foreign Application Priority Data
Sep. 1, 2008 (KR) 10-2008-0085861

(51) Int. Cl. H01L 21/336; C08F 118/16; G03F 7/00

(52) U.S. Cl. 438/158; 526/326; 430/285.1; 430/323; 257/E21.414

(57) ABSTRACT

The present invention relates to a photoresist composition that comprises a resin that is represented by Formula 1, a method for forming a thin film pattern, and a method for manufacturing a thin film transistor array panel by using the same.

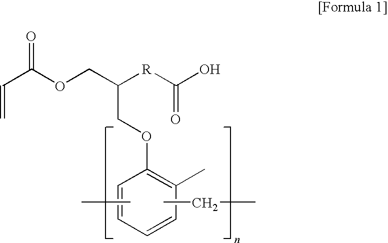

Herein, R is a methylene group, and n is an integer of 1 or more.

This application claims priority to Korean Patent Application No. 10-2008-0085861, filed on Sep. 1, 2008, and all the benefits accruing therefrom under 35 U.S.C. §119, the entire contents of which in its entirety are herein incorporated by reference.

### BACKGROUND OF THE INVENTION

(a) Field of the Invention

The present disclosure relates to a photoresist composition, a method for forming a thin film pattern, and a method for manufacturing a thin film transistor array panel that uses the same.

(b) Description of the Related Art

A liquid crystal display is one of flat panel displays that are currently extensively used in computers and televisions. Liquid crystal displays generally include two display panels on which field generating electrodes are formed. They also include a liquid crystal layer that is disposed between the two display panels. By applying a voltage to the electrodes to rearrange the liquid crystal molecules of the liquid crystal layer, the amount of light that penetrates the two displays is controlled thereby producing a visual image.

As the size of the liquid crystal displays are enlarged, the cost of masks that are used in the process are increased. In addition, the cost for maintaining and managing the mask is also increased. It is therefore desirable to avoid using a mask and to resort to a method of controlling light exposure by using a method that includes digital exposure. The digital exposure is a manner in which, a digital micromirror device (DMD) is used to control light exposure. The light exposure is controlled by the DMD using CAD (computer aided design) data. However, because of differences in the amount of light in a beam that is focused to a spot, the shapes of displayed images are deformed at the interfaces of the exposed pattern. As a result, the pattern profile becomes very poor.

In addition, the compositions for photoresist patterns that are extensively used include a novolac resin that includes methacresol, paracresol, xylenol, or a mixture thereof. In other cases, the photoresist patterns can comprise a mixture of an acryl resin and a novolac. Alternatively, only an acryl resin can be used as the photoresist pattern.

In those cases where only the novolac resin is used, a rapid and strong curing reaction occurs, that later prevents the stripping (e.g., etching) of the novolac resin. The same problem occurs when acryl resin mixed with the novolac resin is used as a photoresist. The use of an acryl resin in the photoresist produce an additional problems.

Since the acryl resin cures at a significantly lower rate than the novolac resin, a difference in the relative solubility of the respective polymers is magnified. This results in non-uniformity and to dimensional differences in the exposed portion and non-exposed portions of the photoresist, which in turn causes a distortion of the pattern leading to low resolution of the etched pattern.

The aforementioned information disclosed in this background is only for enhancement of the understanding of the technology and therefore may contain information that does not form prior art to the disclosed invention.

### BRIEF SUMMARY OF THE INVENTION

It is therefore desirable to provide a photoresist composition that has a good pattern profile, excellent etching characteristics with respect to a stripping solution, and that is capable of realizing excellent resolution.

In one embodiment, a photoresist composition comprises a resin that is represented by Formula 1:

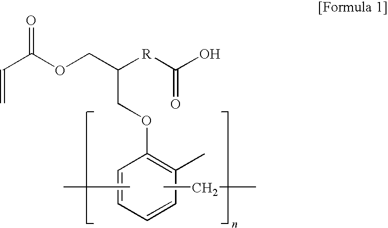

where R is a methylene group, and n is an integer of about 1 or more.

The photoresist composition may further comprise a novolac resin, an acryl-based resin, a triazine derivative, a melamine-based resin, and a polymerization solvent.

In one embodiment, the photoresist composition comprises about 1 to about 50 weight percent (“wt %”) of the novolac resin or the acryl-based resin, about 0.1 to about 5 wt % of the triazine derivative, about 1 to about 10 wt % of the melamine-based resin, about 1 to about 30 wt % of the resin that is represented by Formula 1, with the remainder being the polymerization solvent, based on 100 wt % of the photoresist composition.

In one embodiment, R, in the Formula 1 may be at least one selected from the group consisting of mono-methylene, di-methylene, and tri-methylene.

In another embodiment, the weight average molecular weight of the novolac resin may be an amount of about 4,000 to about 12,000.

In yet another embodiment, the novolac resin may be obtained by polymerizing an aldehyde and a phenol in the presence of an acid catalyst.

The aldehyde may be selected from the group consisting of formaldehyde, benzaldehyde, nitrobenzaldehyde, acetaldehyde, furfural, and a combination comprising at least one of the foregoing aldehydes.

The phenol may be selected from the group consisting of o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone mono-methylether, pyrogallol, fluoroglycinol, hydroxydiphenyl, bisphenol A, gallic acid, gallic acid ester, α-naphthol, β-naphthol, and a combination comprising at least one of the foregoing phenols.

The acryl-based resin may be selected from the groups consisting of acrylic acid, methacrylic acid, benzyl methaacrylate, styrene, hydroxyethyl methacrylate, glycidyl methacrylate, and a combination comprising at least one of the foregoing acryl-based resins.

The weight average molecular weight of the resin that is represented by Formula 1 may be in an amount of about 4,000 to about 20,000.

In yet another embodiment a method for forming a thin film pattern comprises layering a thin film on a substrate; coating the photoresist composition that comprises a novolac resin, an acryl-based resin, a triazine derivative, a melamine-based resin, a resin that is represented by Formula 1, and a polymerization solvent on the thin film; exposing the photoresist composition; developing the exposed photoresist composition to form a photoresist pattern; etching the thin film by using the photoresist pattern as a mask; and stripping the photoresist pattern:

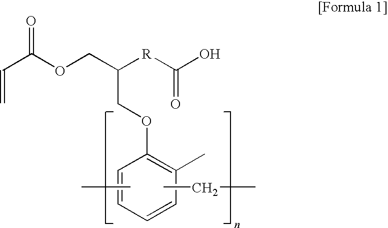

where R is a methylene group, and n is an integer of about 1 or more.

The photoresist composition may comprise about 1 to about 50 wt % of the novolac resin or the acryl-based resin, about 0.1 to about 5 wt % of the triazine derivative, about 1 to about 10 wt % of the melamine-based resin, about 1 to about 30 wt % of the resin that is represented by Formula 1, with the remainder being the polymerization solvent, based on 100 wt % of the photoresist composition.

R, in the Formula 1 may be selected from the group consisting of mono-methylene, di-methylene, and tri-methylene.

In one embodiment, the method may further comprise, before and after the photoresist composition is exposed, first and second bake steps that comprise heating the photoresist composition to cure the photoresist composition.

A profile angle of the photoresist pattern may be in an amount of about 75 to about 90° (degrees).

A line width of the photoresist pattern may be in an amount of about 3.8 to about 4.5 μm (micrometers).

A stripping time of the photoresist pattern may be in an amount of about 5 to about 50 seconds.

In developing the photoresist composition, a trimethylammonium hydroxide (TMAH) solution may be used.

In the exposing step, a digital exposure method may be used.

In yet another embodiment, a method for manufacturing a thin film transistor array panel comprises forming a gate line; forming a gate insulating layer on the gate line; forming a semiconductor layer on the gate insulating layer; forming a data line that comprises a source electrode and a drain electrode that face the source electrode on the semiconductor layer; forming a passivation layer on the data line and the drain electrode; and forming a pixel electrode on the passivation layer, and at least one of the steps selected from the group consisting of forming the gate line, forming the gate insulating layer, forming a semiconductor layer, forming the data line and drain electrode, forming the passivation layer, and forming the pixel electrode uses a photolithography process using a photoresist composition that comprises a novolac resin, an acryl-based resin, a triazine derivative, a melamine-based resin, a resin that is represented by Formula 1, and a polymerization solvent:

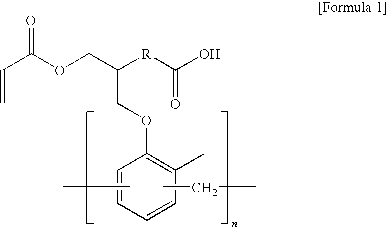

where R is a methylene group, n is an integer of about 1 or more.

At least one of the steps of forming the gate line, forming the gate insulating layer, forming the semiconductor layer, forming the data line and drain electrode, forming the passivation layer, and forming the pixel electrode may use the digital exposure method. More than one of the foregoing processes may employ the digital exposure method if so desired.

In another embodiment, a photoresist composition is applied with a desired pattern profile angle of about 75 to about 90 degrees to obtain a uniform pattern and to increase the pattern resolution.

In addition, a stripping characteristic of a photoresist with respect to an organic solvent that is used as a stripping solution may be improved.

### BRIEF DESCRIPTION OF THE DRAWINGS

The above and other aspects, advantages, and features of the invention will become more apparent by describing in further detail exemplary embodiments thereof with reference to the attached drawings, in which:

FIG. 1A is a scanning electron micrograph (“SEM”) photograph that illustrates a cross-sectional view of a photoresist pattern that is formed in Example 1 of the present invention.

FIG. 1B is a SEM photograph that illustrates a cross-sectional view of a photoresist pattern that is formed in Example 2 of the present invention.

FIG. 1C is a SEM photograph that illustrates a cross-sectional view of a photoresist pattern that is formed in the Comparative Example of the present invention.

FIG. 2A is a SEM photograph of an adjacent photoresist pattern formed in Example 1 of the present invention, which is observed from above.

FIG. 2B is a SEM photograph of an adjacent photoresist pattern formed in Example 2 of the present invention, which is observed from above.

FIG. 2C is a SEM photograph of an adjacent photoresist pattern formed in the Comparative Example of the present invention, which is observed from above.

FIG. 3 is an exemplary layout view that illustrates a structure of a thin film transistor array panel for a liquid crystal display according to an exemplary embodiment of the present invention.

FIG. 4 is an exemplary cross-sectional view of the thin film transistor array panel of FIG. 3 taken along the line IV-IV.

FIGS. 5 to 14 are exemplary cross-sectional views that sequentially illustrate the production of the thin film transistor array panels of FIGS. 3 and 4.

### DETAILED DESCRIPTION OF THE EMBODIMENTS

Details of the exemplary embodiments are included in the following detailed description and the drawings.

These advantages and features, and methods of achieving the present invention will become apparent and more readily appreciated from the following description of the embodiments in conjunction with the accompanying drawings. However, the present invention is not limited to exemplary embodiments that are disclosed below, and may be implemented in various forms. It will be appreciated by those skilled in the art that changes may be made in these embodiments without departing from the principles and spirit of the general inventive concept, the scope of which is defined in the appended claims and their equivalents.

Aspects, advantages, and features of the present invention and methods of accomplishing the same may be understood more readily by reference to the following detailed description of preferred embodiments and the accompanying drawings. The present invention may, however, may be embodied in many different forms, and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer, or section from another region, layer or section. Thus, a first element, component, region, layer, or section discussed below could be termed a second element, component, region, layer, or section without departing from the teachings of the present invention.

Spatially relative terms, such as “below”, “lower”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “lower” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings. However, the aspects, features, and advantages of the present invention are not restricted to the ones set forth herein. The above and other aspects, features and advantages of the present invention will become more apparent to one of ordinary skill in the art to which the present invention pertains by referencing a detailed description of the present invention given below.

The photoresist composition will now be described in detail.

The photoresist composition includes a novolac resin, an acryl-based resin, a triazine derivative, a melamine-based resin, a resin that is represented by Formula 1, and a polymerization solvent.

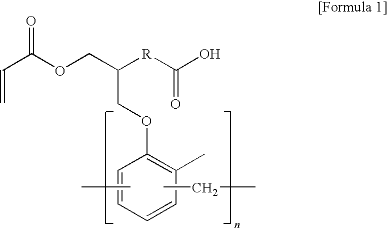

In the Formula 1, R is a methylene group, and n is an integer of about 1 or more.

The photoresist composition includes about 1 to about 50 wt % of the novolac resin or the acryl-based resin, about 0.1 to about 5 wt % of the triazine derivative, about 1 to about 10 wt % of the melamine-based resin, about 1 to about 30 wt % of the resin that is represented by the Formula 1, with the remainder being the polymerization solvent, based on 100 wt % of the composition.

The novolac resin is obtained by polymerizing an aldehyde and a phenol in the presence of an acid catalyst, and it is desirable that the weight average molecular weight of the novolac resin is an amount of about 4,000 to about 12,000.

The aldehyde that is used may be selected from the group consisting of formaldehyde, benzaldehyde, nitrobenzaldehyde, acetaldehyde, furfural, and a combination comprising at least one of the foregoing aldehydes.

In addition, the phenol may be selected from the group consisting of o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone mono-methylether, pyrogallol, fluoroglycinol, hydroxydiphenyl, bisphenol A, gallic acid, gallic acid ester, α-naphthol, β-naphthol, and a combination comprising at least one of the foregoing phenols.

Further, the acryl-based resin that is capable of being used instead of the novolac resin may be selected from the group consisting of an acrylic acid, a methacrylic acid, benzyl methacrylate, styrene, hydroxyethyl methacrylate, glycidyl methacrylate, and a combination comprising at least one of the foregoing acryl-based resins.

The triazine derivative acts as an acid generating agent that directly or indirectly generates an acid when irradiated by electromagnetic radiation, specifically by visible light or ultraviolet light.

The melamine-based resin acts as a cross-linking agent that provides mechanical strength such as hardness or elasticity as well as chemical stability to the resin.

The resin that is represented by Formula 1 is a deformed novolac resin compound, and it is desirable that the weight average molecular weight thereof is an amount of about 4,000 to about 20,000, and R may be at least one selected from the group consisting of mono-methylene, di-methylene, and tri-methylene.

The polymerization solvent includes polymers that have an ethylene double bond, and the like. In general, it is desirable to use an acryl-based polymer or a vinyl-based polymer as the polymerization solvent.

In one embodiment, an acryl resin is substituted in the molecular structure of the novolac resin to permit characteristics of an aromatic compound and characteristics of an acryl compound to occur in one single molecular chain. This facilitates excellent stripping characteristics of the photoresist from the thin film, maintains excellent resolution of the photoresist and maintains a desirable pattern profile angle.

Hereinafter, through examples and a comparative example, the present invention will be described in more detail, and the following examples are set forth to illustrate the invention but are not to be construed to limit the present invention.

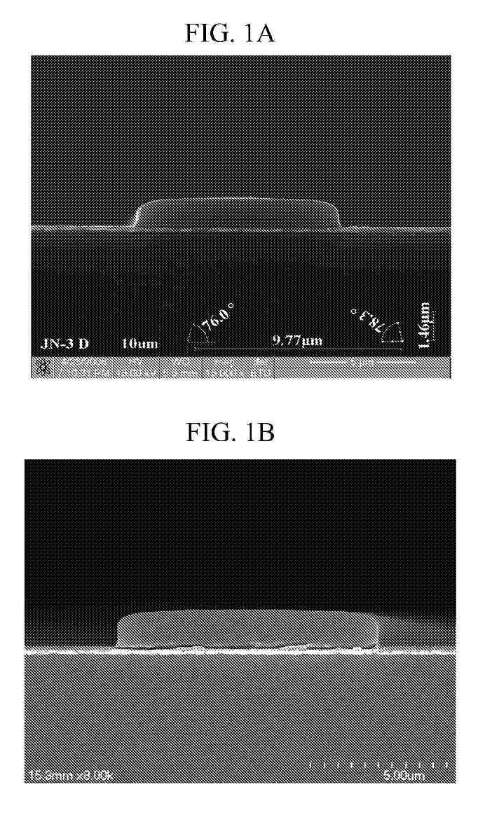

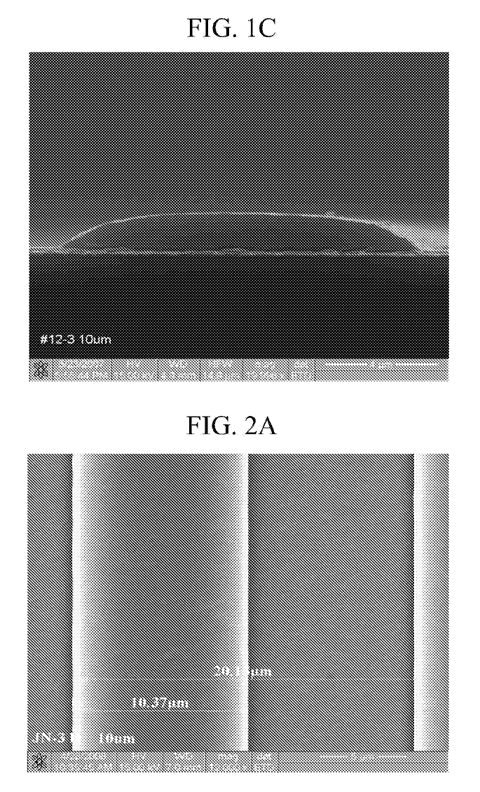

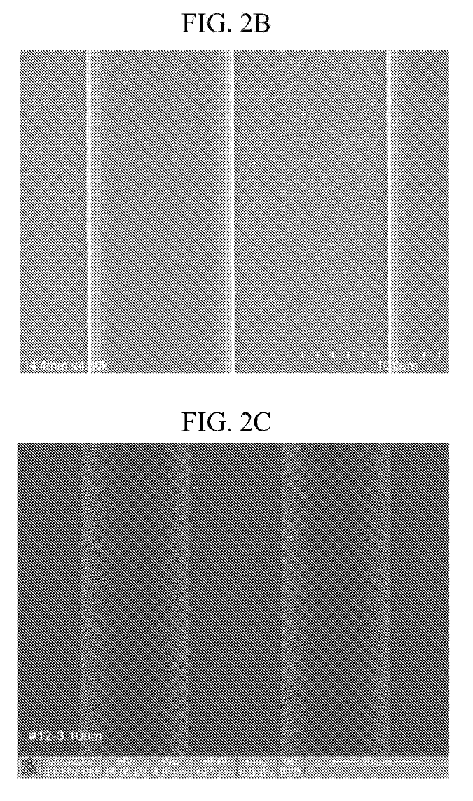

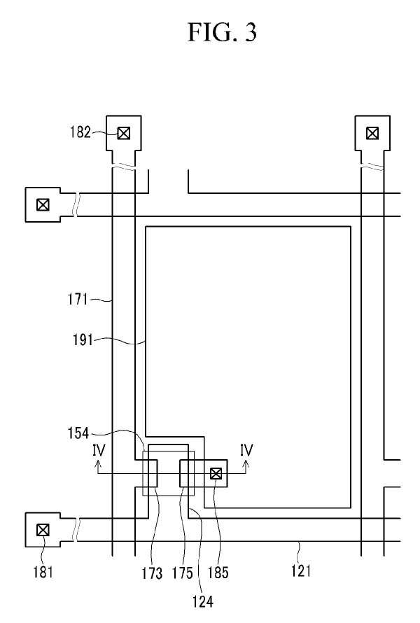

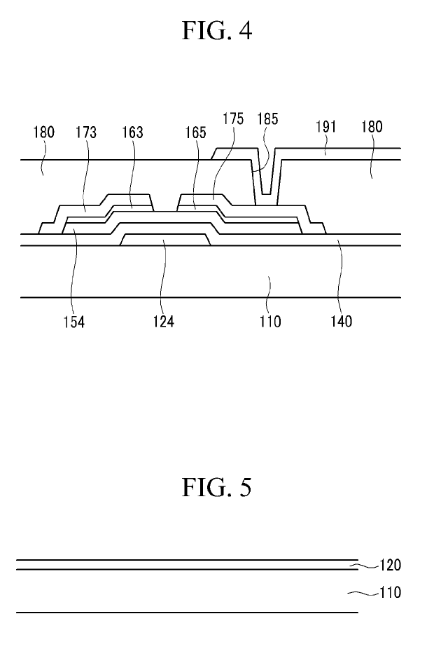

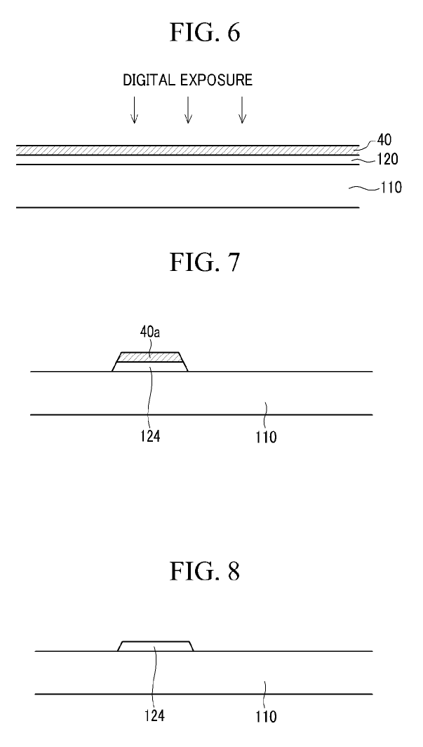

Hereinafter, through FIGS. 1A to 2C, an exemplary embodiment of the present invention will be described.

### EXAMPLE

In the examples of the present invention, a display panel that includes a gate line and a data line is formed.

### Example 1

First, a photoresist composition that includes 15 wt % of the novolac resin, 1 wt % of the triazine derivative that generates a strong acid when irradiated by ultraviolet light, 5 wt % of the melamine-based resin, 74 wt % of propylene glycol monomethyl ether acetate, and 5 wt % of the resin that is represented by the following Formula 1 was produced.

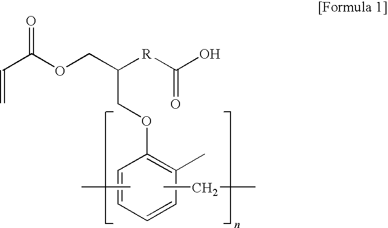

Here, R is a methylene group, and n is an integer of 1 or more.

Next, a substrate that has dimensions of width×length=300 (millimeters) mm×400 mm was prepared, and the produced photoresist composition was spin-coated on to the substrate.

Next, after the substrate on which the photoresist composition is spin-coated was baked at about 120° C., it was subjected to digital exposure, baked again at about 130° C., and developed for about 60 sec in a 2.38 wt % trimethyl ammonium hydroxide (TMAH) aqueous solution. By using a scanning electronic microscope (SEM), the pattern profile angle and the resolution were measured. Further, after the stripper (AZ REMOVER 550M) was heated to about 60° C., the time that was required to completely strip the photoresist composition from the substrate was also measured.

### Example 2

First, a photoresist composition that includes 5 wt % of the novolac resin, 1 wt % of the triazine derivative that generates a strong acid by irradiation with ultraviolet light, 5 wt % of the melamine-based resin, 74 wt % of propylene glycol monomethyl ether acetate, and 15 wt % of the resin that is represented by the following Formula 1 was produced.

Next, a substrate that has dimensions of width×length=300 mm×400 mm was prepared, and the produced photoresist composition was spin-coated on to the substrate.

Next, after the substrate on which the photoresist composition is spin-coated was baked at about 120° C., it was subjected to digital exposure, baked again at about 130° C., and developed for about 60 seconds in a 2.38 wt % trimethyl ammonium hydroxide (TMAH) aqueous solution. By using a scanning electronic microscope (SEM), the pattern profile angle and the resolution were measured. Further, after the stripper (AZ REMOVER 550M) was heated to about 60° C., the time that was required to completely strip the photoresist composition from the substrate was also measured.

### Comparative Example

In the present comparative example, the conditions were the same as those of Examples 1 and 2, but a different photoresist composition was used to perform the test.

First, a photoresist composition that includes 20 wt % of the novolac resin including 60 wt % of meta-cresol and 40 wt % of para-cresol, 1 wt % of the triazine derivative that generates a strong acid when irradiated with ultraviolet light, 5 wt % of the melamine-based resin, and 74 wt % of propylene glycol monomethyl ether acetate was produced.

Next, the substrate that has dimensions of width×length=300 mm×400 mm was prepared, and the produced photoresist composition was spin-coated on to the substrate.

Next, after the substrate on which the photoresist composition is spin-coated was baked at about 120° C., it was subjected to digital exposure, baked again at about 130° C., and developed for about 60 seconds in a 2.38 wt % trimethyl ammonium hydroxide (TMAH) aqueous solution. By using a scanning electronic microscope (SEM), the pattern profile angle and the resolution were measured. In addition, after the stripper (AZ REMOVER 550M) was heated to about 60° C., the time that was required to completely strip the photoresist composition from the substrate was measured.

The pattern profile angles of Example 1, Example 2, and the comparative example are described in Table 1.

TABLE 1

| | Example 1 | Example 2 | Comparative Example |
|---|---|---|---|
| Angle (°) | 76 | 87 | 33 |

As shown in Table 1, in those cases where the photoresist compositions according to Examples 1 and 2 are spin-coated on the substrate, exposed, and developed, pattern profile angles of 76° and 87° were obtained, and the photosensitive film patterns had excellent etching characteristics when compared with the comparative example in which the profile angle of the pattern was 33°.

FIGS. 1A and 1B are SEM photographs that illustrate cross-sectional views of photoresist patterns that are formed in Examples 1 and 2, and FIG. 1C is a SEM photograph that illustrates a cross-sectional view of a photoresist pattern that is formed in the comparative example.

The photoresist pattern profile angle according to Example 1 of FIG. 1A was 76°, and the photoresist pattern profile angle according to Example 2 of FIG. 1B was 87°. On the other hand, the photoresist pattern profile angle according to the comparative example of FIG. 1C was measured as 33°. Thus, in the case where the photoresist composition of the present invention was applied to an exposing and a developing process, it was excellent and displayed etching characteristics where the process applicability was high as compared with known exposure processes that use a mask.

The resolutions of Example 1, Example 2, and the comparative example are described in Table 2 in micrometers.

TABLE 2

| | Example 1 | Example 2 | Comparative Example |
|---|---|---|---|
| Resolution (μm) | 4.3 | 4.0 | 5.0 |

As shown in Table 2, in those cases where the photoresist compositions according to Examples 1 and 2 of the present invention are spin-coated on the substrate, exposed, and developed, the minimum line widths of 4.3 μm and 4.0 μm were obtained, which represent excellent resolutions when compared with the case of the comparative example where the minimum line width of 5.0 μm was obtained.

FIGS. 2A and 2B are SEM photographs of adjacent photoresist patterns formed in Examples 1 and 2 of the present invention, where the observation is made from above the photoresist pattern (e.g., a top view), and FIG. 2C is a SEM photograph of an adjacent photoresist pattern formed using the comparative example, which is observed from above as well (also a top view).

The minimum line width of the photoresist pattern according to Example 1 of FIG. 2A was 4.3 μm, and the minimum line width of the photoresist pattern according to Example 2 of FIG. 2B was 4.0 μm. On the other hand, the minimum line width of the photoresist pattern according to the comparative example of FIG. 2C was measured at 5.0 μm. Thus, in the case of when the photoresist compositions of the present invention was applied to an exposing process and a developing process, it could be seen that excellent resolution and clean and stable images are obtained.

Stripping characteristics of Example 1, Example 2, and the comparative example are described in Table 3.

TABLE 3

| | Example 1 | Example 2 | Comparative Example |
|---|---|---|---|
| Stripping time (sec) | 40 | 10 | 200 |

As shown in Table 3, when the photoresist compositions according to Examples 1 and 2 are spin-coated on the substrate, exposed, and developed, the time that was utilized to completely strip the photoresist composition from the substrate was 40 seconds and 10 seconds respectively, which was an excellent stripping characteristic as compared with the case of the comparative example in which the stripping time was 200 seconds.

Hereinafter, a method for manufacturing a thin film transistor array panel by using the disclosed photoresist composition will be described.

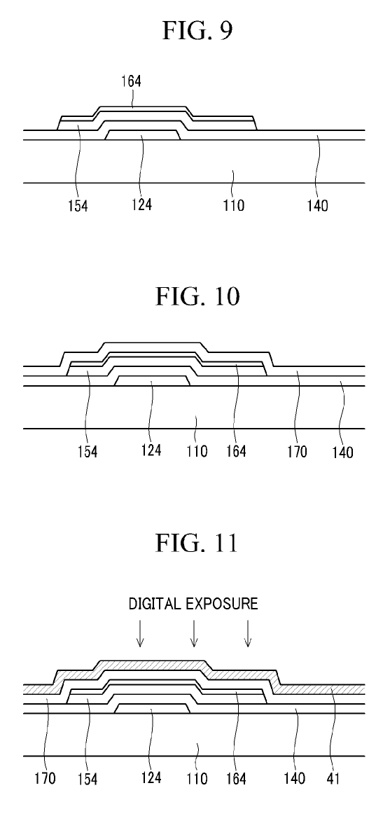

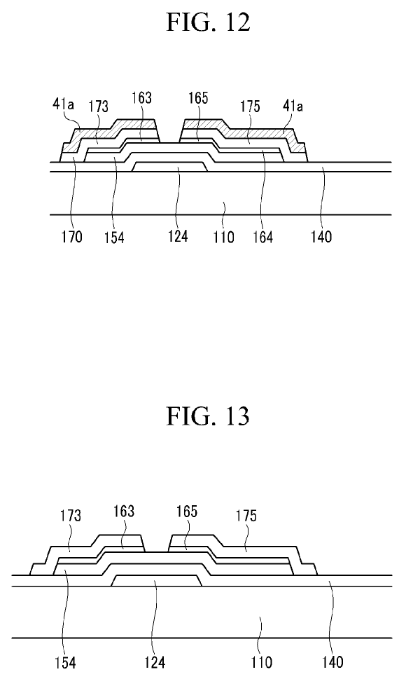

FIG. 3 is a layout view that illustrates a structure of a thin film transistor array panel for liquid crystal display according to an exemplary embodiment of the present invention, and FIG. 4 is a cross-sectional view of the thin film transistor array panel of FIG. 3 taken along the line IV-IV.

A plurality of gate lines 121 that transmit a gate signal are formed on an insulation substrate 110. The gate lines 121 extend in a horizontal direction, and a portion of the gate lines 121 form a plurality of gate electrodes 124.

The gate lines 121 may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), and titanium (Ti). However, these may have a multilayer structure that includes two conductive layers (not shown) having different physical properties.

A gate insulating layer 140 is formed on the gate lines 121, and a semiconductor island layer 154 and ohmic contact layers 163 and 165 are formed thereon. On the ohmic contact layers 163 and 165 and the gate insulating layer 140, a plurality of data lines 171 and a plurality of drain electrodes 175 are formed, respectively.

The data lines 171 extend in a vertical direction, cross the gate lines 121, and transmit data voltage. A plurality of branches that extend from the data lines 171 to the drain electrode 175 form the source electrodes 173. A pair of source electrodes 173 and drain electrodes 175 that are separated from each other are disposed opposite to each other with respect to a gate electrode 124.

The data lines 171 and the drain electrodes 175 may be made of a refractory metal such as molybdenum, chromium, tantalum, and titanium, or an alloy thereof, and they may have a multilayer structure that includes a refractory metal film (not shown) and a low resistance conductive layer (not shown). Examples of the multilayer structure include a double layer of a chromium or molybdenum (alloy) that form the lower layer and an aluminum (alloy) that forms the upper layer, or a triple layer that includes a molybdenum (alloy) lower layer, an aluminum (alloy) intermediate layer, and a molybdenum (alloy) upper layer. The data lines 171 and the drain electrodes 175 may be made of various metals or conductors in addition to these.

The gate electrode 124, the source electrode 173, and the drain electrode 175 form a thin film transistor (TFT) in conjunction with the semiconductor island layer 154, and a channel of the thin film transistor is formed on the semiconductor island layer 154 between the source electrode 173 and the drain electrode 175.

On the data line 171 and the drain electrode 175, a passivation layer 180 having contact holes 185 is formed, and a pixel electrode 191 is formed thereon.

By manufacturing the thin film transistor array panel of this structure through a photolithography process using the photoresist composition that includes the resin of Formula 1, a fine and precise thin film pattern may be obtained.

A method for manufacturing the thin film transistor array panel that is shown in FIGS. 3 and 4 according to an exemplary embodiment of the present invention will now be described in detail with reference to FIGS. 5 to 14 and FIGS. 3 and 4.

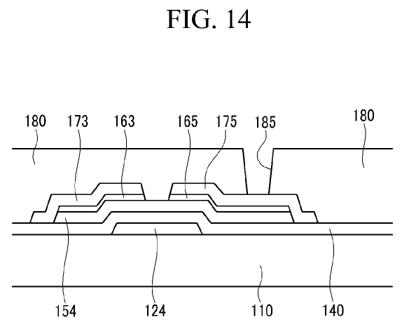

FIGS. 5 to 14 are cross-sectional views that sequentially illustrate the manufacturing of the thin film transistor array panel of FIGS. 3 and 4.

First, as shown in FIG. 5, a metal layer 120 is formed on an insulating substrate 110.

Next, as shown in FIG. 6, by coating the photoresist composition 40 that includes the novolac resin, the acryl-based resin, the triazine derivative, the melamine-based resin, the resin that is represented by Formula 1 and the polymerization solvent according to an exemplary embodiment of the present invention, performing the digital exposure, and developing it, as shown in FIG. 7, a predetermined photoresist pattern 40a is formed. At this time, the profile angle of the formed photoresist pattern 40a is in an amount of about 75 to about 90°.

The digital exposure method is a method in which, when predetermined pattern data are inputted into a digital exposing machine, the digital exposing machine controls the turning on and off of a micro-mirror (according to data acquired from the pattern condition) to selectively irradiate the photoresist composition 40, to obtain the desired pattern. A laser of a single wavelength may be used as the light source.

When the photoresist pattern 40a is formed, an exposure method in which the exposure is carried out by using an optical mask may be used. In addition, the method may further include, first and second bake steps for heating the photoresist composition and curing it. In one embodiment, the first and the second bake steps may be conducted before and after the photoresist composition 40 is exposed respectively.

Subsequently, the metal layer 120 is etched by using the photoresist pattern 40a as an etching mask.

Next, as that is shown in FIG. 8, the photoresist pattern 40a is stripped away by using a photoresist stripping agent. The stripping time of the photoresist pattern 40a may be for a time period of about 5 to about 50 seconds.

Next, as shown in FIG. 9, the gate insulating layer 140 that is made of silicon oxide or silicon nitride, the semiconductor layer comprising the amorphous silicon layer, and the amorphous silicon layer on which an n-type impurity are doped are sequentially deposited and subjected to photolithography to form a semiconductor island layer 154 and an impurity semiconductor pattern 164 on the gate insulating layer 140. When the semiconductor island layer 154 and the impurity semiconductor pattern 164 are formed, the photoresist composition that includes the resin that is represented by Formula 1 may be used, and the digital exposure method may also be used.

Next, as shown in FIG. 10, a metal layer 170 is deposited on the impurity semiconductor pattern 164 and the gate insulating layer 140 by using a sputtering method.

Continuously, as shown in FIG. 11, a photoresist composition 41 according to an exemplary embodiment of the present invention is coated on the metal layer 170, is subjected to the digital exposure, and is developed, and as shown in FIG. 12, a predetermined photoresist pattern 41a is formed. At this time, the profile angle of the formed photoresist pattern 41a is in the range of about 75 to about 90°.

In addition, before and after the photoresist composition 41 is exposed, the method may further include the first and second bake steps in which the photoresist composition is heated and cured.

While the photoresist pattern 41a is used as the etching mask, the metal layer 170 is etched to form the source electrode 173 and the drain electrode 175. The processes displayed in the FIGS. 10, 11 and 12 may be conducted continuously or a batch processes.

Next, as shown in FIG. 13, the photoresist pattern 41a is stripped by using a photoresist stripping agent. The stripping time of the photoresist pattern 41a may be used for a time period of about 5 to about 50 seconds.

By continuously removing a portion of the impurity semiconductor layer that is not covered with the source electrode 173 and the drain electrode 175 but is exposed, a plurality of ohmic contact island layers 163 and 165 are formed, and the semiconductor island 154 therebeneath is exposed.

Next, as shown in FIG. 14, the inorganic insulator that is made of a material such as silicon oxide or silicon nitride is deposited or the organic insulator such as the resin is coated to form a passivation layer 180, and the photolithography is carried out to form a contact hole 185 to expose the drain electrode 175. At this time, contact holes 181 and 182 (see FIG. 3) for exposing an end portion of the data line 171 and an end portion of the gate line 121 may be formed in conjunction therewith. In the case where the contact hole 181 for exposing the end portion of the gate line 121 is formed, the gate insulating layer 140 is etched. When the contact hole 185 is formed, the photoresist composition that includes the resin of Formula 1 may be used and the digital exposure method may be used.

Next, as shown in FIG. 4, a transparent conductor such as indium tin oxide (ITO) or indium zinc oxide (IZO), or a metal that has a good reflectivity such as aluminum, is deposited on the passivation layer 180 and subjected to photolithography to form a pixel electrode 191. When the pixel electrode 191 is formed, the photoresist composition that includes the resin of Formula 1 may be used and the digital exposure method may be used.

The exemplary embodiments of the present invention have been described and shown with reference to the accompanying drawings, but the present invention is not limited to the exemplary embodiments and may be manufactured in various forms. As described above, it will be appreciated by those skilled in the art that changes may be made in these embodiments without departing from the principles and spirit of the general inventive concept, the scope of which is defined in the appended claims and their equivalents. Therefore, it should be understood that the exemplary embodiments described above are not limitative but are exemplary in all the aspects.

What is claimed is:

1. A photoresist composition comprising
a resin that is represented by Formula 1: 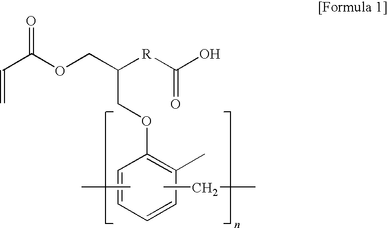
where R is a methylene group, and n is an integer of about 1 or more.

2. The photoresist composition of claim 1, further comprising a novolac resin, an acryl-based resin, a triazine derivative, a melamine-based resin, and a polymerization solvent.

3. The photoresist composition of claim of claim 2, wherein the photoresist composition comprises about 1 to about 50 weight percent of the novolac resin or the acryl-based resin, about 0.1 to about 5 weight percent of the triazine derivative, 1 to 10 weight percent of the melamine-based resin, 1 to 30 weight percent of the resin that is represented by Formula 1, with the remainder being a polymerization solvent, based on 100 weight percent of the photoresist composition.

4. The photoresist composition of claim 3, wherein R is selected from the group consisting of mono-methylene, di-methylene, and tri-methylene.

5. The photoresist composition of claim 3, wherein the weight average molecular weight of the novolac resin is an amount of about 4,000 to about 12,000.

6. The photoresist composition of claim 5, wherein the novolac resin is obtained by polymerizing an aldehyde and a phenol in the presence of an acid catalyst.

7. The photoresist composition of claim 6, wherein
the aldehyde is selected from the group consisting of formaldehyde, benzaldehyde, nitrobenzaldehyde, acetaldehyde, furfural and a combination comprising at least one of the foregoing aldehydes.

8. The photoresist composition of claim 6, wherein the phenol is selected from the group consisting of o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone mono-methylether, pyrogallol, fluoroglycinol, hydroxydiphenyl, bisphenol A, gallic acid, gallic acid ester, α-naphthol, β-naphthol, and a combination comprising at least one of the foregoing phenols.

9. The photoresist composition of claim 3, wherein the acryl-based resin is selected from the group consisting of acrylic acid, methacrylic acid, benzyl methaacrylate, styrene, hydroxyethyl methacrylate, glycidyl methacrylate, and a combination comprising at least one of the foregoing acryl-based resins.

10. The photoresist composition of claim 3, wherein the weight average molecular weight of the resin that is represented by Formula 1 is about 4,000 to about 20,000.

11. A method for forming a thin film pattern, the method comprising:
layering a thin film on a substrate;
coating a photoresist composition that comprises a novolac resin, an acryl-based resin, a triazine derivative, a melamine-based resin, a resin that is represented by Formula 1, and a polymerization solvent on the thin film; 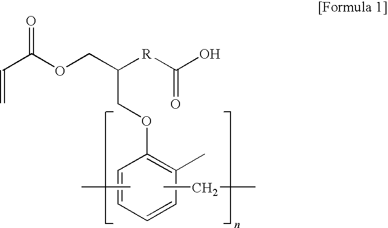
wherein R is a methylene group, and n is an integer of 1 or more;
exposing the photoresist composition to electromagnetic radiation;
developing the exposed photoresist composition to form a photoresist pattern;
etching the thin film by using the photoresist pattern as a mask; and
stripping the photoresist pattern.

12. The method for forming a thin film pattern of claim 11, wherein
the photoresist composition comprises about 1 to about 50 wt % of the novolac resin or the acryl-based resin, about 0.1 to about 5 wt % of the triazine derivative, about 1 to about 10 wt % of the melamine-based resin, about 1 to about 30 wt % of the resin that is represented by Formula 1, with the remainder being the polymerization solvent, based on 100 wt % of the photoresist composition.

13. The method for forming a thin film pattern of claim 11, wherein R is selected from the group consisting of mono-methylene, di-methylene, and tri-methylene.

14. The method for forming a thin film pattern of claim 11, further comprising performing a first and second bake of the photoresist composition to cure the photoresist composition; the first bake being conducted prior to exposing the photoresist composition, while the second bake is conducted after the exposing of the photoresist composition.

15. The method for forming a thin film pattern of claim 11, wherein
the photoresist pattern has a profile angle of about 75 to about 90 degrees.

16. The method for forming a thin film pattern of claim 11, wherein the line width of the photoresist pattern is in the range of 3.8 to 4.5 micrometers.

17. The method for forming a thin film pattern of claim 11, wherein the stripping the photoresist pattern is conducted for a time period of about 5 to about 50 seconds.

18. The method for forming a thin film pattern of claim 17, wherein, trimethylammonium hydroxide (TMAH) solution is used in the developing the exposed photoresist composition to form a photoresist pattern.

19. The method for forming a thin film pattern of claim 11, wherein a digital exposure method is used in the exposing the photoresist composition to electromagnetic radiation.

20. A method for manufacturing a thin film transistor array panel, the method comprising:
forming a gate line on a substrate;
forming a gate insulating layer on the gate line;
forming a semiconductor layer on the gate insulating layer;
forming a data line that comprises a source electrode and a drain electrode on the semiconductor layer; the drain electrode facing the source electrode;
forming a passivation layer on the data line and the drain electrode; and
forming a pixel electrode on the passivation layer,
wherein at least one of the steps selected from the group consisting of forming the gate line, forming the gate insulating layer, forming the semiconductor layer, forming the data line and the drain electrode, forming the passivation layer, and forming the pixel electrode uses a photolithography process that uses a photoresist composition that comprises a novolac resin, an acryl-based resin, a triazine derivative, a melamine-based resin, a resin that is represented by Formula 1, and a polymerization solvent: 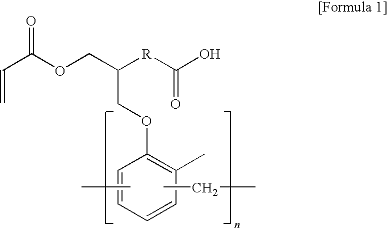
wherein R is a methylene group, and n is an integer of about 1 or more.

21. The method for manufacturing a thin film transistor array panel of claim 20, wherein
at least one of the steps selected from the group consisting of forming the gate line, forming the gate insulating layer, forming the semiconductor layer, forming the data line and the drain electrode, forming the passivation layer, and forming the pixel electrode uses a digital exposure method.
